(19) United States
(12) Patent Application Publication
(10) Pub. No.: US 2018/0163322 A1
(43) Pub. Date: Jun. 14, 2018

(54) MECHANICALLY STRENGTHENED BOND BETWEEN THERMALLY STABLE POLYCRYSTALLINE HARD MATERIALS AND HARD COMPOSITES

(71) Applicant: Halliburton Energy Services, Inc., Houston, TX (US)

(72) Inventors: Gagan Saini, Conroe, TX (US); Qi Liang, Richmond, VA (US)

(73) Assignee: Halliburton Energy Services, Inc., Houston, TX (US)

(21) Appl. No.: 14/787,172

(22) PCT Filed: Dec. 22, 2014
(86) PCT No.: PCT/US2014/071894

§ 371 Date: Oct. 26, 2015

(51) Int. Cl. C30B 29/04; C30B 33/12; B23B 27/14; B23B 27/20; E21B 10/567; E21B 10/573

(52) U.S. Cl. CPC C30B 29/04; C30B 33/12; B23B 27/146; B23B 2240/08; E21B 10/5676; E21B 10/5735; B23B 2226/315; B23B 27/20

(57) ABSTRACT

The strength of the bond formed by a braze material between a polycrystalline hard material and a hard composite may be physically strengthened. For example, a method of physical strengthening may include etching a bonding surface of a polycrystalline material body to produce a synthetic topography on the bonding surface of the polycrystalline material body, the bonding surface opposing a contact surface of the polycrystalline material body; and brazing the bonding surface of the polycrystalline material body having the synthetic topography to a bonding surface of a hard composite using a braze material.

### BACKGROUND

The present application relates to bonding hard composites to polycrystalline materials, including but not limited to, polycrystalline diamond (“PCD”) materials and thermally stable polycrystalline (“TSP”) materials.

Drill bits and components thereof are often subjected to extreme conditions (e.g., high temperatures, high pressures, and contact with abrasive surfaces) during subterranean formation drilling or mining operations. Hard materials like diamond, cubic boron nitride, and silicon carbide are often used at the contact points between the drill bit and the formation because of their wear resistance, hardness, and ability to conduct heat away from the point of contact with the formation.

Generally, such hard materials are formed by combining particles of the hard material and a catalyst, such that when heated the catalyst facilitates growth and/or binding of the material so as to bind the particles together to form a polycrystalline material. However, the catalyst remains within the body of the polycrystalline material after forming. Because the catalyst generally has a higher coefficient of thermal expansion than the hard material, the catalyst can cause fractures throughout the polycrystalline material when the polycrystalline material is heated (e.g., during brazing to attach the polycrystalline material to the drill bit or a portion thereof like a cutter or during operation downhole). These fractures weaken the polycrystalline material and may lead to a reduced lifetime for the drill bit.

To mitigate fracturing of the polycrystalline material, it is common to remove at least some of the catalyst, and preferably most of the catalyst, before exposing the polycrystalline material to elevated temperatures. Polycrystalline materials that have a substantial amount of the catalyst removed are referred to as thermally stable polycrystalline (“TSP”) materials.

Specifically for drill bits, TSP materials are often bonded to another material (e.g., a hard composite like tungsten carbide particles dispersed in a copper binder) to allow the more expensive TSP materials to be strategically located at desired contact points with the formation. However, separation of the TSP material and the surface to which it is bonded during operation reduces the efficacy and lifetime of the drill bit.

### BRIEF DESCRIPTION OF THE DRAWINGS

The following figures are included to illustrate certain aspects of the embodiments, and should not be viewed as exclusive embodiments. The subject matter disclosed is capable of considerable modifications, alterations, combinations, and equivalents in form and function, as will occur to those skilled in the art and having the benefit of this disclosure.

FIG. 1 is a cross-sectional view of a matrix drill bit having a matrix bit body formed by a hard composite material.

FIG. 2 is an isometric view of the matrix drill bit that includes polycrystalline material cutters according to at least some embodiments of the present disclosure.

FIG. 3 is a cross-sectional view of a cutter according to at least some embodiments of the present disclosure.

FIG. 4 is a cross-sectional view of a cutter according to at least some embodiments of the present disclosure.

FIGS. 5A and 5B illustrate a side-view and a top view of a mask disposed on the bonding surface of a polycrystalline material body.

FIG. 6 is a schematic drawing showing one example of a drilling assembly suitable for use in conjunction with the matrix drill bits that include cutters of the present disclosure.

### DETAILED DESCRIPTION

The present application relates to bonding polycrystalline materials to hard composites when forming abrasive components of downhole tools (e.g., cutters for use in drill bits). More specifically, the present application relates to physical methods for increasing the strength of the bond formed by a braze material between the polycrystalline materials and the hard composite. The teachings of this disclosure can be applied to any downhole tool or component thereof where polycrystalline materials are bonded to a hard composite. Such tools may include tools for drilling wells, completing wells, and producing hydrocarbons from wells. Examples of such tools include cutting tools, such as drill bits, reamers, stabilizers, and coring bits; drilling tools, such as rotary steerable devices and mud motors; and other tools used downhole, such as window mills, packers, tool joints, and other wear-prone tools.

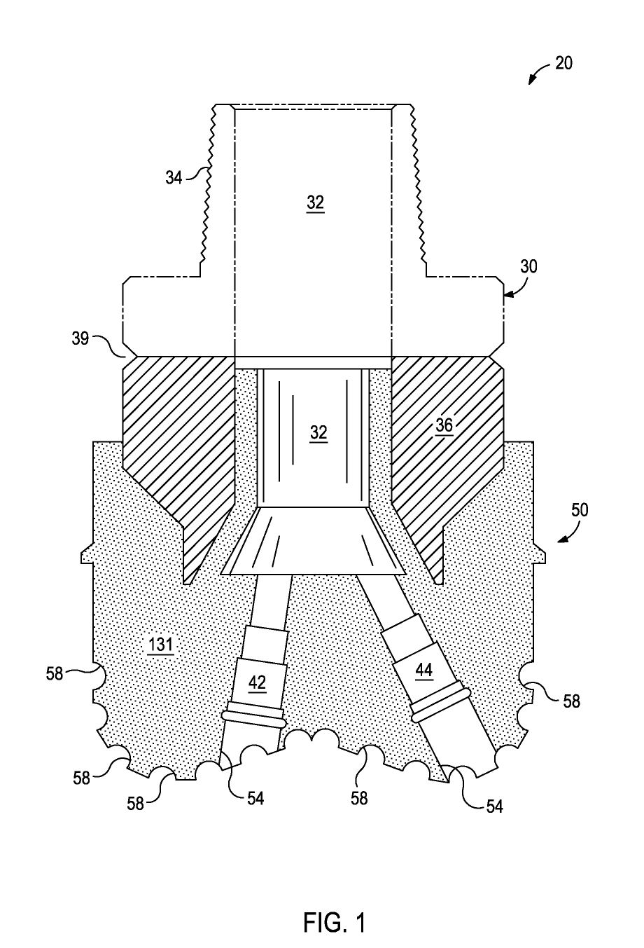

FIG. 1 is a cross-sectional view of a matrix drill bit 20 having a matrix bit body 50 formed by a hard composite material 131. An exemplary hard composite material may include, but not be limited to, reinforcing particles dispersed in a binder material. As used herein, the term “matrix drill bit” encompasses rotary drag bits, drag bits, fixed cutter drill bits, and any other drill bit having a matrix bit body and capable of incorporating the teachings of the present disclosure.

For embodiments such as those shown in FIG. 1, the matrix drill bit 20 may include a metal shank 30 with a metal blank 36 securely attached thereto (e.g., at weld location 39). The metal blank 36 extends into matrix bit body 50. The metal shank 30 includes a threaded connection 34 distal to the metal blank 36.

The metal shank 30 and metal blank 36 are generally cylindrical structures that at least partially define corresponding fluid cavities 32 that fluidly communicate with each other. The fluid cavity 32 of the metal blank 36 may further extend longitudinally into the matrix bit body 50. At least one flow passageway (shown as two flow passageways 42 and 44) may extend from the fluid cavity 32 to exterior portions of the matrix bit body 50. Nozzle openings 54 may be defined at the ends of the flow passageways 42 and 44 at the exterior portions of the matrix bit body 50.

A plurality of indentations or pockets 58 are formed in the matrix bit body 50 and are shaped or otherwise configured to receive cutters.

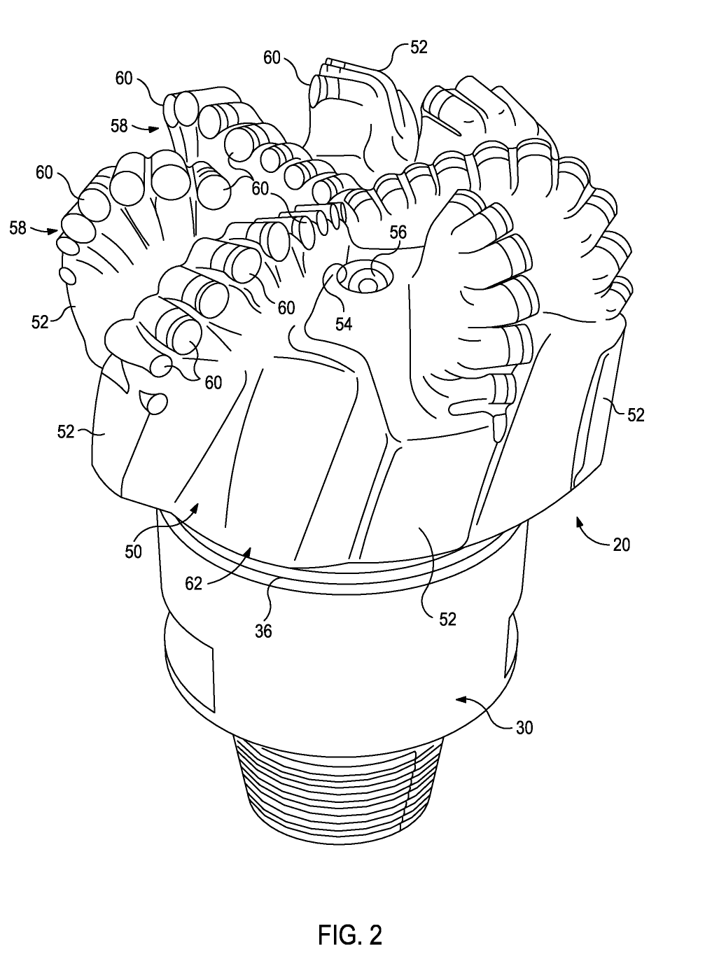

FIG. 2 is an isometric view of the matrix drill bit that includes a plurality of cutters 60 according to at least some embodiments of the present disclosure. As illustrated, the matrix drill bit 20 includes the metal blank 36 and the metal shank 30, as generally described above with reference to FIG. 1.

The matrix bit body 50 includes a plurality of cutter blades 52 formed on the exterior of the matrix bit body 50. Cutter blades 52 may be spaced from each other on the exterior of the matrix bit body 50 to form fluid flow paths or junk slots 62 therebetween.

As illustrated, the plurality of pockets 58 may be formed in the cutter blades 52 at selected locations. A cutter 60 may be securely mounted (e.g., via brazing) in each pocket 58 to engage and remove portions of a subterranean formation during drilling operations. More particularly, each cutter 60 may scrape and gouge formation materials from the bottom and sides of a wellbore during rotation of the matrix drill bit 20 by an attached drill string.

A nozzle 56 may be disposed in each nozzle opening 54. For some applications, nozzles 56 may be described or otherwise characterized as “interchangeable” nozzles.

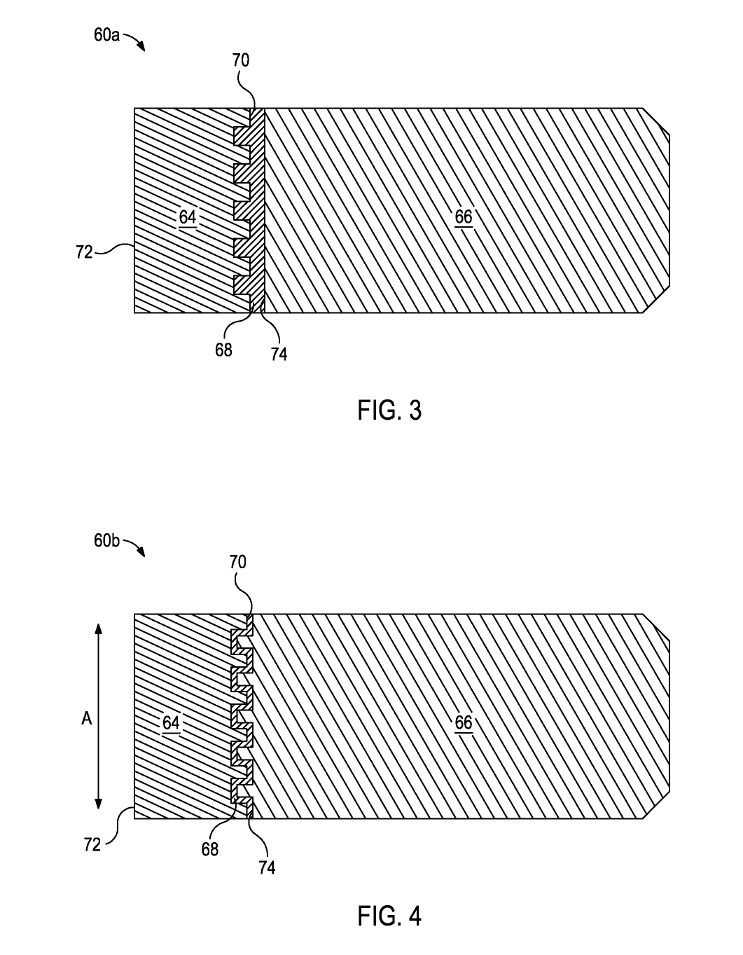

FIG. 3 is a cross-sectional view of an exemplary cutter 60a, according to at least some embodiments of the present disclosure. The cutter 60a is formed by a polycrystalline material body 64 bonded to a hard composite body 66 with braze 68. More specifically, the polycrystalline material body 64 may define and otherwise provide a bonding surface 70 opposite a cutting surface 72 of the polycrystalline material body 64. Moreover, the hard composite body 66 may define and otherwise provide a bonding surface 74. The corresponding bonding surfaces 70, 74 of the polycrystalline material body 64 and the hard composite body 66, respectively, may be coupled and otherwise bonded together with the braze 68 (e.g., alloys of at least two of silver, copper, nickel, titanium, vanadium, phosphorous, silicon, aluminum, molybdenum and the like).

Examples of polycrystalline materials suitable for use as the polycrystalline material body 64 may include, but are not limited to, polycrystalline diamond, polycrystalline cubic boron nitride, polycrystalline silicon carbide, TSP diamond, TSP cubic boron nitride, TSP silicon carbide, and the like.

In some embodiments, as illustrated in FIG. 3, the bonding surface 70 of the polycrystalline material body 64 may exhibit a synthetic topography. As described in more detail above, a polycrystalline material is formed by subjecting small grains of a hard material (e.g., diamond, cubic boron nitride, and silicon carbide) that are randomly oriented and other starting materials (e.g., catalyst) to ultrahigh pressure and temperature conditions. Then, the TSP material may be formed by removing at least a portion of the catalyst from the structure. The resultant surfaces of the polycrystalline material body 64 have some roughness as an artifact of using grains but are generally flat on the macroscopic level. As used herein, the term “synthetic topography” relative to a surface refers to a roughness or unevenness on that surface, which may or may not be in a predetermined pattern, that is purposefully added or imparted on that surface. A synthetic topography is different than the roughness created as a result of fusing the grains together when forming polycrystalline materials. In the illustrated embodiment, for example, the synthetic topography may exhibit a generally castellated or uneven topography.

Without being limited by theory, it is believed that the synthetic topography may prove advantageous in increasing surface area of the bonding surface 70 of the polycrystalline material body 64. The increased bonding surface area may enhance the strength of the bond between the polycrystalline material body 64 and the braze 68, which may mitigate potential separation of the polycrystalline material body 64 from the hard composite body 66 during use downhole.

FIG. 4 is a cross-sectional view of another exemplary cutter 60b, according to at least some embodiments of the present disclosure. Similar to cutter 60a of FIG. 3, the cutter 60b is formed by a polycrystalline material body 64 bonded to a hard composite body 66 with braze 68. As illustrated, the bonding surface 70 of the polycrystalline material body 64 and the bonding surface 74 of the hard composite body 66 each exhibit a synthetic topography and, more particularly, a interleaving uneven topography. In the illustrated embodiment, the synthetic topography of each of the bonding surfaces 70 and 74 are designed to interleave and otherwise interlock with sufficient space for the braze material 68 to bond the adjacent bonding surfaces 70 and 74. In at least one embodiment, the synthetic topography of the each bonding surface 70 and 74 may be designed to fit and otherwise mesh into the other.

Without being limited by theory, it is believed that providing a synthetic topography on the bonding surfaces 70 and 74 of the polycrystalline material body 64 and the hard composite body 66, respectively, may prove advantageous in providing additional mechanical strength to the bond that mitigates shearing of the bond therebetween in the radial direction, which is indicated by directional arrows A of FIG. 4.

In some embodiments, the synthetic topography of the bonding surfaces 70 and 74 may be formed by reactive ion etching with gases like oxygen and tetrafluoromethane. One of skill in the art would recognize the appropriate conditions for performing a reactive ion etch on a hard material (e.g., diamond, cubic boron nitride, and silicon carbide). For example, a reactive ion plasma with oxygen and optionally tetrafluoromethane may be used to etch a polycrystalline material. More specifically, one example of suitable conditions of a reactive ion plasma etch of diamond and other polycrystalline materials may, in some instances, include a reaction gas of 40 parts oxygen and 0 parts to 40 parts tetrafluoromethane, a total gas pressure of 50 mTorr, a radio-frequency power of 100 W to 400 W at 13.56 MHz, and a bonding surface 70,74 temperature of 0° C. to 5° C. With adjustments to the radio-frequency power, the total gas pressure, reaction gas compositions, and bonding surface 70,74 temperature may be adjusted outside the ranges provided.

In some embodiments, etched portions of the bonding surfaces 70,74 may have a depth (i.e., an average distance extending into the respective body) of 5 microns to 1 mm, including subsets therebetween (e.g., 5 microns to 100 microns, 50 microns to 500 microns, or 250 microns to 1 mm). The depth may depend on, inter alia, the etching conditions, the amount of time the etching is performed, and the composition of the hard composite and the hard material.

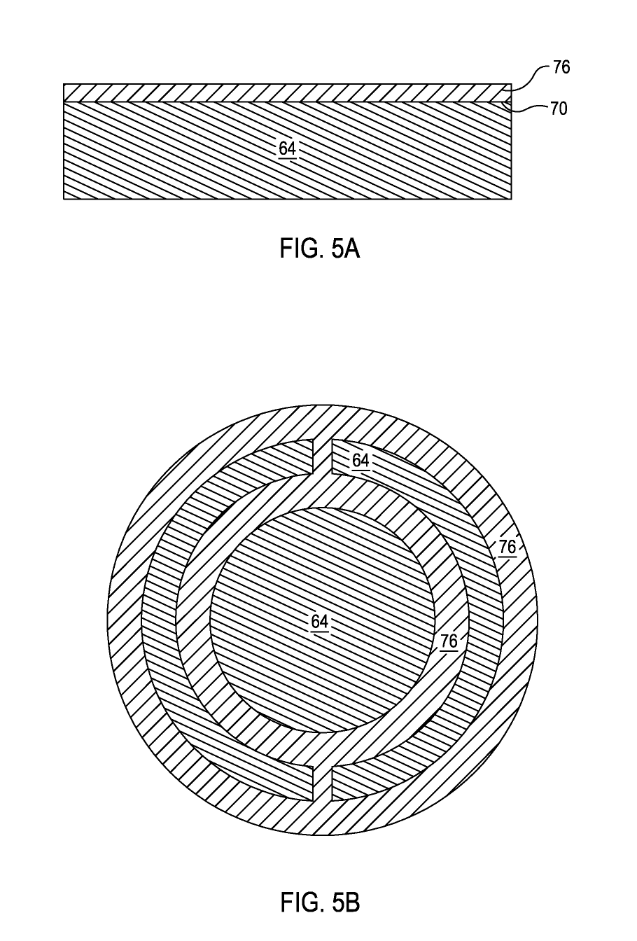

In some embodiments, when forming the synthetic topography, a mask may be used to etch only a portion of the bonding surface 70,74. FIGS. 5A and 5B illustrate a side-view and a top view, respectively, of a mask 76 disposed on the bonding surface 70 of a polycrystalline material body 64. As best seen in FIG. 5B, the mask 76 covers only a portion of the bonding surface 70 such that the exposed portions of the bonding surface 70 may be etched during the etching procedure. Masks may be useful in forming a pattern on the bonding surface 70 of a polycrystalline material body 64. However, in some instances, random etching may be accomplished without the use of a mask.

Masks may be formed by any known methods (e.g., photomasking) with materials suitable for withstanding the etching processes. Examples of materials suitable for use as a mask may include, but are not limited to, silicon oxide, metallic films, photoresist materials, and the like.

Masks may be used to form any pattern, for example, squares, concentric circles, stripes, and the like.

Examples of hard composites that may be useful for bonding to a polycrystalline material body having a bonding surface with a crystal structure described herein may be formed by reinforcing particles dispersed in a binder material. Exemplary binder materials may include, but are not limited to, copper, nickel, cobalt, iron, aluminum, molybdenum, chromium, manganese, tin, zinc, lead, silicon, tungsten, boron, phosphorous, gold, silver, palladium, indium, any mixture thereof, any alloy thereof, and any combination thereof. Nonlimiting examples of binder materials may include copper-phosphorus, copper-phosphorous-silver, copper-manganese-phosphorous, copper-nickel, copper-manganese-nickel, copper-manganese-zinc, copper-manganese-nickel-zinc, copper-nickel-indium, copper-tin-manganese-nickel, copper-tin-manganese-nickel-iron, gold-nickel, gold-palladium-nickel, gold-copper-nickel, silver-copper-zinc-nickel, silver-manganese, silver-copper-zinc-cadmium, silver-copper-tin, cobalt-silicon-chromium-nickel-tungsten, cobalt-silicon-chromium-nickel-tungsten-boron, manganese-nickel-cobalt-boron, nickel-silicon-chromium, nickel-chromium-silicon-manganese, nickel-chromium-silicon, nickel-silicon-boron, nickel-silicon-chromium-boron-iron, nickel-phosphorus, nickel-manganese, copper-aluminum, copper-aluminum-nickel, copper-aluminum-nickel-iron, copper-aluminum-nickel-zinc-tin-iron, and the like, and any combination thereof. Exemplary reinforcing particles may include, but are not limited to, particles of metals, metal alloys, metal carbides, metal nitrides, diamonds, superalloys, and the like, or any combination thereof. Examples of reinforcing particles suitable for use in conjunction with the embodiments described herein may include particles that include, but not be limited to, nitrides, silicon nitrides, boron nitrides, cubic boron nitrides, natural diamonds, synthetic diamonds, cemented carbide, spherical carbides, low alloy sintered materials, cast carbides, silicon carbides, boron carbides, cubic boron carbides, molybdenum carbides, titanium carbides, tantalum carbides, niobium carbides, chromium carbides, vanadium carbides, iron carbides, tungsten carbides, macrocrystalline tungsten carbides, cast tungsten carbides, crushed sintered tungsten carbides, carburized tungsten carbides, steels, stainless steels, austenitic steels, ferritic steels, martensitic steels, precipitation-hardening steels, duplex stainless steels, ceramics, iron alloys, nickel alloys, chromium alloys, HASTELLOY® alloys (nickel-chromium containing alloys, available from Haynes International), INCONEL® alloys (austenitic nickel-chromium containing superalloys, available from Special Metals Corporation), WASPALOYS® (austenitic nickel-based superalloys, available from United Technologies Corp.), RENE® alloys (nickel-chrome containing alloys, available from Altemp Alloys, Inc.), HAYNES® alloys (nickel-chromium containing superalloys, available from Haynes International), INCOLOY® alloys (iron-nickel containing superalloys, available from Mega Mex), MP98T (a nickel-copper-chromium superalloy, available from SPS Technologies), TMS alloys, CMSX® alloys (nickel-based superalloys, available from C-M Group), N-155 alloys, any mixture thereof, and any combination thereof.

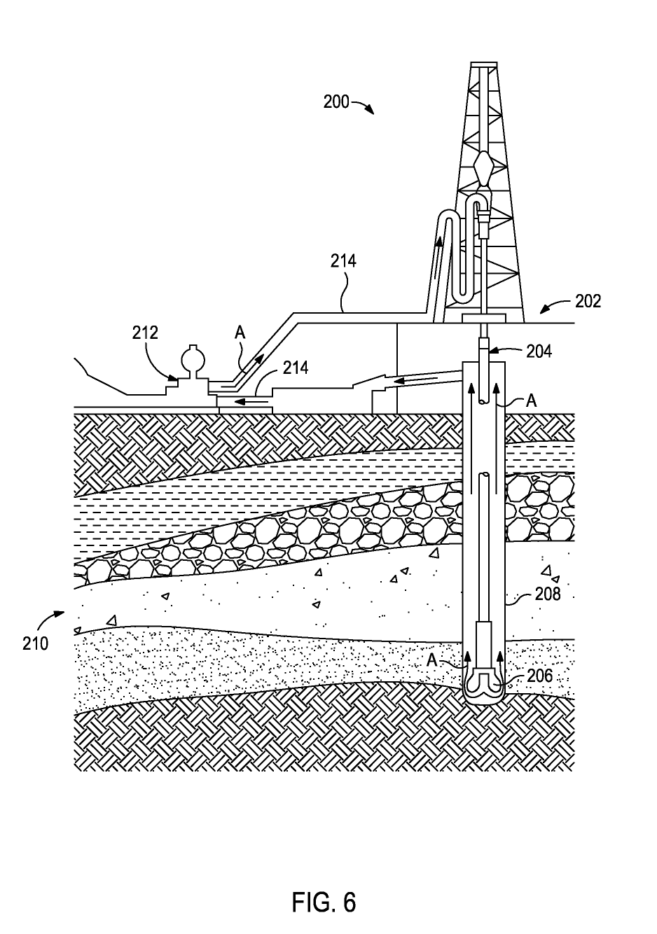

FIG. 6 is a schematic showing one example of a drilling assembly 200 suitable for use in conjunction with matrix drill bits that include cutters of the present disclosure (e.g., cutter 60 of FIGS. 2-3). It should be noted that while FIG. 6 generally depicts a land-based drilling assembly, those skilled in the art will readily recognize that the principles described herein are equally applicable to subsea drilling operations that employ floating or sea-based platforms and rigs, without departing from the scope of the disclosure.

The drilling assembly 200 includes a drilling platform 202 coupled to a drill string 204. The drill string 204 may include, but is not limited to, drill pipe and coiled tubing, as generally known to those skilled in the art apart from the particular teachings of this disclosure. A matrix drill bit 206 according to the embodiments described herein is attached to the distal end of the drill string 204 and is driven either by a downhole motor and/or via rotation of the drill string 204 from the well surface. As the drill bit 206 rotates, it creates a wellbore 208 that penetrates the subterranean formation 210. The drilling assembly 200 also includes a pump 212 that circulates a drilling fluid through the drill string 204 (as illustrated as flow arrows A) and other pipes 214.

One skilled in the art would recognize the other equipment suitable for use in conjunction with drilling assembly 200, which may include, but is not limited to, retention pits, mixers, shakers (e.g., shale shaker), centrifuges, hydrocyclones, separators (including magnetic and electrical separators), desilters, desanders, filters (e.g., diatomaceous earth filters), heat exchangers, and any fluid reclamation equipment. Further, the drilling assembly 200 may include one or more sensors, gauges, pumps, compressors, and the like.

Embodiments disclosed herein include:
A. a method that includes etching a bonding surface of a polycrystalline material body to produce a synthetic topography on the bonding surface of the polycrystalline material body, the bonding surface opposing a contact surface of the polycrystalline material body; and brazing the bonding surface of the polycrystalline material body having the synthetic topography to a bonding surface of a hard composite using a braze material;
B. a method that includes applying a first mask to a bonding surface of a polycrystalline material body and thereby providing one or more polycrystalline masked portions and one or more polycrystalline exposed portions, the bonding surface opposing a contact surface of the polycrystalline material body; etching the one or more polycrystalline exposed portions to produce a synthetic topography on the bonding surface of the polycrystalline material body; removing the first mask from the bonding surface of the polycrystalline material body; and brazing the bonding surface of the polycrystalline material body having the synthetic topography to a bonding surface of a hard composite using a braze material;
C. a cutting element that includes a polycrystalline material body having a bonding surface with a synthetic topography, the bonding surface opposing a contact surface of the polycrystalline material body; and a hard composite having a bonding surface bound to the bonding surface of the polycrystalline material body with a braze material; and
D. a drilling assembly that induces a drill string extendable from a drilling platform and into a wellbore; a pump fluidly connected to the drill string and configured to circulate a drilling fluid into the drill string and through the wellbore; and a drill bit attached to an end of the drill string, the drill bit having a matrix bit body and a plurality of cutting elements formed by Embodiment A, formed by Embodiment B, according to Embodiments C, or a combination thereof coupled to an exterior portion of the matrix bit body.

Embodiments A and B may have one or more of the following additional elements in any combination: Element 1: the method further including etching the bonding surface of the polycrystalline material body with a reactive ion plasma comprising oxygen to produce the synthetic topography; Element 2: the method further including etching the bonding surface of the polycrystalline material body with a reactive ion plasma comprising oxygen and tetrafluoromethane to produce the synthetic topography; Element 3: wherein brazing the bonding surface of the polycrystalline material body having the synthetic topography to the bonding surface of the hard composite is preceded by: etching the bonding surface of the hard composite to produce a synthetic topography on the bonding surface of the hard composite body; Element 4: wherein brazing the bonding surface of the polycrystalline material body having the synthetic topography to the bonding surface of the hard composite is preceded by: applying a mask (or a second mask) to the bonding surface of the hard composite and thereby providing one or more hard composite masked portions and one or more hard composite exposed portions; etching the one or more hard composite exposed portions to produce a synthetic topography on the bonding surface of the hard composite; and removing the mask (or the second mask) from the bonding surface of the hard composite; Element 5: the method with either Element 3 or Element 4, wherein the synthetic topography on the bonding surface of the hard composite body includes etched portions of the bonding surface of the hard composite body that are 5 microns to 1 mm deep; and Element 6: wherein the synthetic topography on the bonding surface of the polycrystalline material body includes etched portions of the bonding surface of the polycrystalline material body that are 5 microns to 1 mm deep. Embodiment B may also include: Element 7: the method with Element 4 and further including forming the synthetic topography of the bonding surface of the polycrystalline material body and the synthetic topography of the bonding surface of the hard composite to be interlocking. By way of non-limiting example, exemplary combinations may include: Element 1 in combination with Element 2 and optionally Element 3 and optionally Element 5; Element 1 in combination with Element 2 and optionally Element 4 and optionally Elements 5 and/or 7; Element 1 in combination with Element 3 and optionally Element 5; Element 1 in combination with Element 4 and optionally Elements 5 and/or 7; Element 2 in combination with Element 3 and optionally Element 5; Element 2 in combination with Element 4 and optionally Elements 5 and/or 7; Element 6 in combination with at least one of Elements 1-5 and optionally Element 7 including in the foregoing combinations.

Embodiment C may have one or more of the following additional elements in any combination: Element 8: wherein the bonding surface of the hard composite has a synthetic topography; Element 9: Element 8 wherein the synthetic topography of the bonding surface of the polycrystalline material body and the synthetic topography of the bonding surface of the hard composite are interlocking; Element 10: Element 8 wherein the synthetic topography on the bonding surface of the hard composite body includes etched portions of the bonding surface of the hard composite body that are 5 microns to 1 mm deep; and Element 11: wherein the synthetic topography on the bonding surface of the polycrystalline material body includes etched portions of the bonding surface of the polycrystalline material body that are 5 microns to 1 mm deep. By way of non-limiting example, exemplary combinations may include: Element 8 in combination with Elements 9-10 and optionally Element 11; Elements 8 and 11 in combination; Elements 8, 9, and 11 in combination; and Elements 8, 10, and 11 in combination.

One or more illustrative embodiments incorporating the invention embodiments disclosed herein are presented herein. Not all features of a physical implementation are described or shown in this application for the sake of clarity. It is understood that in the development of a physical embodiment incorporating the embodiments of the present invention, numerous implementation-specific decisions must be made to achieve the developer's goals, such as compliance with system-related, business-related, government-related and other constraints, which vary by implementation and from time to time. While a developer's efforts might be time-consuming, such efforts would be, nevertheless, a routine undertaking for those of ordinary skill in the art and having benefit of this disclosure.

While compositions and methods are described herein in terms of “comprising” various components or steps, the compositions and methods can also “consist essentially of” or “consist of” the various components and steps. Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present invention. The invention illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

The invention claimed is:

1. A method comprising:
etching a bonding surface of a polycrystalline material body to produce a synthetic topography on the bonding surface of the polycrystalline material body, the bonding surface opposing a contact surface of the polycrystalline material body; and
brazing the bonding surface of the polycrystalline material body having the synthetic topography to a bonding surface of a hard composite using a braze material.

2. The method of claim 1, wherein the synthetic topography on the bonding surface of the polycrystalline material body includes etched portions of the bonding surface of the polycrystalline material body that are 5 microns to 1 mm deep.

3. The method of claim 1 further comprising:
etching the bonding surface of the polycrystalline material body with a reactive ion plasma comprising oxygen to produce the synthetic topography.

4. The method of claim 1 further comprising:
etching the bonding surface of the polycrystalline material body with a reactive ion plasma comprising oxygen and tetrafluoromethane to produce the synthetic topography.

5. The method of claim 1, wherein brazing the bonding surface of the polycrystalline material body having the synthetic topography to the bonding surface of the hard composite is preceded by:
etching the bonding surface of the hard composite to produce a synthetic topography on the bonding surface of the hard composite body.

6. The method of claim 5, wherein the synthetic topography on the bonding surface of the hard composite body includes etched portions of the bonding surface of the hard composite body that are 5 microns to 1 mm deep.

7. A method comprising:
applying a first mask to a bonding surface of a polycrystalline material body and thereby providing one or more polycrystalline masked portions and one or more polycrystalline exposed portions, the bonding surface opposing a contact surface of the polycrystalline material body;
etching the one or more polycrystalline exposed portions to produce a synthetic topography on the bonding surface of the polycrystalline material body;
removing the first mask from the bonding surface of the polycrystalline material body; and
brazing the bonding surface of the polycrystalline material body having the synthetic topography to a bonding surface of a hard composite using a braze material.

8. The method of claim 7, wherein the synthetic topography on the bonding surface of the polycrystalline material body includes etched portions of the bonding surface of the polycrystalline material body that are 5 microns to 1 mm deep.

9. The method of claim 7 further comprising:
etching the one or more polycrystalline exposed portions with a reactive ion plasma comprising oxygen to produce the synthetic topography.

10. The method of claim 7 further comprising:
etching the one or more polycrystalline exposed portions with a reactive ion plasma comprising oxygen and tetrafluoromethane to produce the synthetic topography.

11. The method of claim 7, wherein brazing the bonding surface of the polycrystalline material body having the synthetic topography to the bonding surface of the hard composite is preceded by:
etching the bonding surface of the hard composite to produce a synthetic topography on the bonding surface of the hard composite body.

12. The method of claim 11, wherein the synthetic topography on the bonding surface of the hard composite body includes etched portions of the bonding surface of the hard composite body that are 5 microns to 1 mm deep.

13. The method of claim 7, wherein brazing the bonding surface of the polycrystalline material body having the synthetic topography to the bonding surface of the hard composite is preceded by:
applying a second mask to the bonding surface of the hard composite and thereby providing one or more hard composite masked portions and one or more hard composite exposed portions;
etching the one or more hard composite exposed portions to produce a synthetic topography on the bonding surface of the hard composite; and
removing the second mask from the bonding surface of the hard composite.

14. The method of claim 13 further comprising:
forming the synthetic topography on the bonding surface of the polycrystalline material body and the synthetic topography on the bonding surface of the hard composite to be interlocking.

15. The method of claim 13, wherein the synthetic topography on the bonding surface of the hard composite body includes etched portions of the bonding surface of the hard composite body that are 5 microns to 1 mm deep.

16. A cutting element comprising:
a polycrystalline material body having a bonding surface with a synthetic topography, the bonding surface opposing a contact surface of the polycrystalline material body; and
a hard composite having a bonding surface bound to the bonding surface of the polycrystalline material body with a braze material.

17. The cutting element of claim 16, wherein the bonding surface of the hard composite has a synthetic topography.

18. The cutting element of claim 17, wherein the synthetic topography of the bonding surface of the polycrystalline material body and the synthetic topography of the bonding surface of the hard composite are interlocking.

19. A drilling assembly comprising:
a drill string extendable from a drilling platform and into a wellbore;
a pump fluidly connected to the drill string and configured to circulate a drilling fluid into the drill string and through the wellbore; and
a drill bit attached to an end of the drill string, the drill bit having a matrix bit body and a plurality of cutting elements according to claim 16 coupled to an exterior portion of the matrix bit body.
